(19) United States
(12) Patent Application Publication
(10) Pub. No.: US 2025/0022785 A1
(43) Pub. Date: Jan. 16, 2025

(54) SEMICONDUCTOR CHIP AND SEMICONDUCTOR PACKAGE INCLUDING THE SAME

(71) Applicant: SAMSUNG ELECTRONICS CO., LTD., SUWON-SI (KR)

(72) Inventors: PYUNGHWA HAN, SUWON-SI (KR); BONG-SOO KIM, SUWON-SI (KR); GYUJIN CHOI, SUWON-SI (KR)

(21) Appl. No.: 18/410,992

(22) Filed: Jan. 11, 2024

(30) Foreign Application Priority Data
Jul. 12, 2023 (KR) 10-2023-0090675

(51) Int. Cl. H01L 23/498; H01L 23/00; H01L 25/065

(52) U.S. Cl. CPC H01L 23/49816; H01L 23/49822; H01L 24/05; H01L 24/45; H01L 25/0657; H01L 2224/05008; H01L 2224/05024; H01L 2224/45005; H01L 2224/4502; H01L 2225/06517; H01L 2225/06541; H01L 2924/01029; H01L 2924/15311; H01L 2924/18161

(57) ABSTRACT

A semiconductor chip includes a semiconductor substrate, an insulation layer positioned on the semiconductor substrate and that includes a plurality of via holes, and a bump positioned within the plurality of via holes and on the insulation layer. Portions of the bump positioned within the plurality of via holes are connected to each other.

### CROSS-REFERENCE TO RELATED APPLICATION

This application claims priority under 35 U.S.C. § 119 from Korean Patent Application No. 10-2023-0090675, filed in the Korean Intellectual Property Office on Jul. 12, 2023, the contents of which are incorporated herein by reference in their entirety.

### TECHNICAL FIELD

Embodiments of the present disclosure are directed to a semiconductor chip and a semiconductor package that includes the same.

### DISCUSSION OF THE RELATED ART

A redistribution layer (RDL) is a metal layer that is additionally formed to re-arrange bumps already formed on a semiconductor substrate such that they can be used at other desired positions on a chip. To electrically connect a small-sized semiconductor circuit and a large-sized circuit, such as a motherboard circuit, a redistribution layer formed of a laminate of an insulation layer and a conductive layer can be used instead of a PCB.

The redistribution layer is thinner than the PCB, and can be directly formed on the bump during package formation. Accordingly, since a separate connecting member that connects a chip to a pre-manufactured PCB is not required, a package that uses a redistribution layer is usually thinner than a package that uses a PCB.

### SUMMARY

Embodiments of the present disclosure increase the reliability of vias of a redistribution layer formed on a bump of a semiconductor chip.

In an embodiment, a semiconductor chip includes a semiconductor substrate, an insulation layer positioned on the semiconductor substrate and that includes a plurality of via holes, and a bump positioned within the plurality of via holes and on the insulation layer. Portions of the bump positioned within the plurality of via holes are connected to each other.

In an embodiment, a semiconductor chip includes a semiconductor substrate, an insulation layer positioned on the semiconductor substrate and that includes a plurality of via holes, and a bump positioned within the plurality of via holes and on the insulation layer. The bump includes a plurality of first portions positioned within the plurality of via holes, and a second portion that interconnects the plurality of first portions.

In an embodiment, a semiconductor package includes a package substrate that includes a trench, a semiconductor chip positioned within the trench of the package substrate, a redistribution structure positioned on the semiconductor chip, and a connection member connected to the redistribution structure. The semiconductor chip includes a semiconductor substrate, an insulation layer positioned on the semiconductor substrate and that includes a plurality of via holes, and a bump positioned within the plurality of via holes and on the insulation layer. The bump includes a plurality of first portions positioned within the plurality of via holes, and a second portion that interconnects the plurality of first portions.

According to embodiments, reliability of redistribution layer vias can be increased, and an area on the bumps in which vias of the redistribution layer are formed can be substantially increased.

### BRIEF DESCRIPTION OF THE DRAWINGS

FIG. 1 is cross-sectional view of a semiconductor chip of an embodiment.

FIG. 2 is an enlarged view of region A of FIG. 1.

FIG. 3A to FIG. 3C are plan views of bumps of various embodiments.

FIG. 4 is a cross-sectional view of a semiconductor package of an embodiment.

FIG. 5 is an enlarged view of region B of FIG. 4.

FIG. 6 shows a semiconductor chip of an embodiment and second redistribution vias formed on bumps of a semiconductor chip of a comparative example.

FIG. 7 to FIG. 13 illustrate a method of manufacturing a semiconductor chip of an embodiment.

### DETAILED DESCRIPTION

Embodiments of the present disclosure will be described more fully hereinafter with reference to the accompanying drawings, in which embodiments of the disclosure are shown. As those skilled in the art would realize, described embodiments can be modified in various different ways, all without departing from the spirit or scope of the present disclosure.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction. It will be understood that when an element such as a layer, film, region, area, or substrate is referred to as being in contact another element, it is in direct contact with the other element.

Further, throughout the specification, the phrase “in a plan view” means viewing a target portion from the top, and the phrase “in a cross-sectional view” or “on a cross-section” means viewing a cross-section formed by vertically cutting a target portion from the side.

Hereinafter, a semiconductor chip, a semiconductor package, and a method for manufacturing the same of an embodiment are described in detail with reference to the drawings.

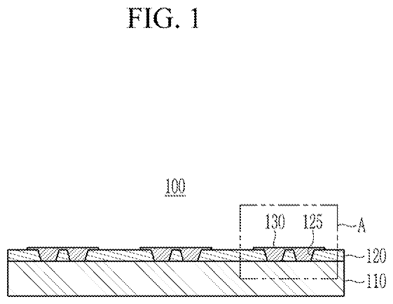

FIG. 1 is a cross-sectional view of a semiconductor chip 100 of an embodiment. Referring to FIG. 1, in an embodiment, the semiconductor chip 100 includes a semiconductor substrate 110, an insulation layer 120, and a bump 130.

The semiconductor substrate 110 includes an integrated circuit formed thereon, and may be referred to as a wafer. For example, the semiconductor substrate 110 may be a silicon wafer. The semiconductor substrate 110 includes an active layer.

The insulation layer 120 is positioned on the semiconductor substrate 110. The insulation layer 120 includes, for example, one or more of photosensitive polyimide (PSPI), silicon nitride, silicon oxide, silicon oxynitride, or a combination thereof. The insulation layer 120 can be formed on the semiconductor substrate 110 by a deposition or coating process. A thickness of the insulation layer 120 is, for example, 3 μm or more and 5 μm or less.

The insulation layer 120 includes a plurality of via holes 125. The plurality of via holes 125 penetrate the insulation layer 120. The plurality of via holes 125 can be formed by photolithography and etching processes. In an embodiment, planar shapes of the plurality of via holes 125 are circular, but are not necessarily limited thereto.

The semiconductor chip 100 includes a plurality of bumps 130. The bumps 130 connect the semiconductor chip 100 to a package substrate or another semiconductor chip. The bump 130 are connected to the active layer of the semiconductor substrate 110.

The bump 130 is positioned within the plurality of via holes 125 and on the insulation layer 120. Portions of the bumps 130 positioned within the plurality of via holes 125 are connected to each other. The portions of the bumps 130 positioned within the plurality of via holes 125 are connected by a portion of the bump 130 positioned on the insulation layer 120. The portions of the bumps 130 positioned within the plurality of via holes 125 and the portions of the bumps 130 positioned on the insulation layer 120 are connected to each other.

The bump 130 covers a first surface of the insulation layer 120 that surrounds open surfaces of the plurality of via holes 125, in a plan view. The bump 130 covers inner walls and bottom surfaces of the plurality of via holes 125.

The bump 130 includes, for example, a metal, such as at least one of copper (Cu), aluminum (Al), gold (Au), silver (Ag) or nickel (Ni). For example, the bump 130 can be formed by a plating or sputtering process. In an embodiment, the bump 130 includes copper (Cu).

In an embodiment, a thickness of the bump 130 is 3 μm or more and 5 μm or less.

In an embodiment, the number of via holes 125 covered by one bump 130 is four, but embodiments are not necessarily limited thereto, and in other embodiments, may be more or less. For example, the number of via holes 125 covered by one bump 130 is four or more.

In an embodiment, the bump 130 has a hexagonal planar shape that covers the plurality of via holes 125, but is necessarily not limited thereto. In other embodiments, the bump 130 can have various other planar shapes, such as a circle or a rectangle.

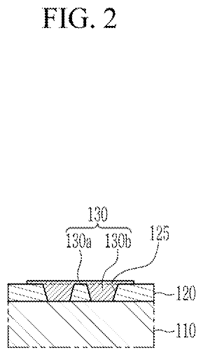

FIG. 2 is an enlarged view of region A of FIG. 1. Referring to FIG. 2, in an embodiment, the bump 130 includes a plurality of first portions 130b and a second portion 130a.

The plurality of first portions 130b are positioned within the plurality of via holes 125. The plurality of first portions 130b cover sidewalls and bottom surfaces of the plurality of via holes 125. The sidewalls of the plurality of via holes 125 are surrounded by the insulation layer 120. The plurality of first portions 130b are surrounded by the insulation layer 120. The bottom surfaces of the plurality of via holes 125 expose a portion of the semiconductor substrate 110. The plurality of first portions 130b are in contact with the semiconductor substrate 110.

The plurality of first portions 130b fill the plurality of via holes 125. The plurality of first portions 130b have a pillar shape in contact with inner walls of the plurality of via holes 125. Side surfaces of the plurality of first portions 130b are in contact with the sidewalls of the plurality of via holes 125. Bottom surfaces of the plurality of first portions 130b are in contact with the bottom surfaces of the plurality of via holes 125. In an embodiment, bottom surfaces of the plurality of first portions 130b are in contact with the exposed portion of the semiconductor substrate 110.

The second portion 130a interconnects the plurality of first portions 130b. The second portion covers the plurality of first portions 130b and a portion of the insulation layer 120 adjacent to the plurality of first portions 130b. The portion of the insulation layer 120 adjacent to the plurality of first portions 130b includes the portion of the insulation layer 120 that surrounds the plurality of first portions 130b.

Upper surfaces of the plurality of first portions 130b are in contact with the second portion 130a. The upper surfaces of the plurality of first portions 130b are in contact with a bottom surface of the second portion 130a. The bottom surface of the second portion 130a is in contact with the upper surfaces of the plurality of first portions 130b and an upper surface of the insulation layer 120 adjacent to the plurality of first portions 130b.

An upper surface of the second portion 130a is flat. Being flat means that any step that may be present between a portion of the second portion 130a that covers the insulation layer 120 and a portion of the second portion 130a that covers the plurality of first portions 130b is within a preset range. Since the upper surface of the second portion 130a is flat, an interface in contact with the upper surface of the second portion 130a is flat, and accordingly, reliability of a via formed on the second portion 130a is increased.

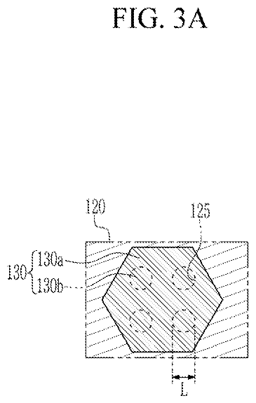

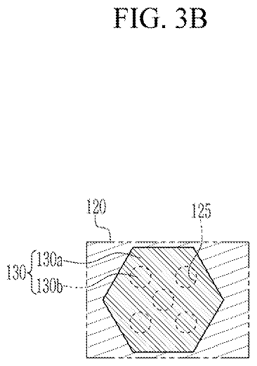

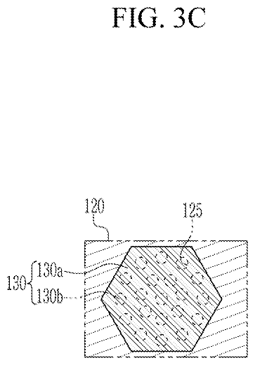

FIG. 3A to FIG. 3C are plan views of the bump 130 of various embodiments. FIG. 3A to FIG. 3C are, for example, plan views of region A of FIG. 1 as viewed from above.

In an embodiment, the bump 130 covers the plurality of via holes 125 and adjacent portions of insulation layer 120. The bump 130 includes the plurality of first portions 130b positioned within the plurality of via holes 125 and the second portion 130a that connects the plurality of first portions 130b. The second portion 130a covers the plurality of first portions 130b and the adjacent portions of the insulation layer 120. The second portion 130a covers the upper surfaces of the plurality of first portions 130b. Although a plurality of first portions 130b are shown in the drawings for purposes of explanation, when the bump 130 is viewed from above, the plurality of first portions 130b are not be visible due to being covered by the second portion 130a.

Referring to FIG. 3A, in an embodiment, the number of via holes 125 covered by the bump 130 is four, but is not necessarily limited thereto. The arrangement of the four via holes 125 is not limited to that shown in FIG. 3A. In an embodiment, the bump 130 has a hexagonal planar shape that covers the four via holes 125, but is not necessarily limited thereto. The bump 130 can have various other shapes, such as a circle, a rectangle, or an octagon.

In an embodiment, the planar shapes of the plurality of via holes 125 are circular, but are not necessarily limited thereto. In an embodiment, a width L of a via hole 125 is 5 μm or more and 10 μm or less. When the width L of the via hole 125 exceeds 10 μm, a step difference between the plurality of first portions 130b and the second portion 130a can increase. When the width L of the via hole 125 is less than 5 μm, the upper surface of the second portion 130a might not be flat. When the upper surface of the second portion 130a is not flat, the reliability of the via formed on the bump 130 decreases. When the width L of the via hole 125 is less than 5 μm, the via hole 125 might not be filled. and the reliability of the electrical connection of the bump 130 can decrease.

The plurality of via holes 125 are uniformly disposed. A distance between the plurality of via holes 125 is constant. The constant distance between the plurality of via holes 125 means that, when the number of via holes 125 is three or more, the distance between a first via hole and a second via hole, the distance between the second via hole and a third via hole, and the distance between the first via hole and the third via hole are substantially equal. For example, the distance between the plurality of via holes 125 is constant at 10 μm or more.

Referring to FIG. 3B, in another embodiment, the number of via holes 125 covered by the bump 130 is five, but is not necessarily limited thereto. The arrangement of the five via holes 125 is not limited to that shown in FIG. 3B. In an embodiment, the bump 130 has a hexagonal planar shape that covers the five via holes 125, but is not necessarily limited thereto. The bump 130 can have various other shapes, such as a circle, a rectangle, or an octagon.

Referring to FIG. 3C, in another embodiment, the number of via holes 125 covered by the bump 130 is twenty, but is not necessarily limited thereto. The arrangement of the twenty via holes 125 is not limited to that shown in FIG. 3C. In an embodiment, the bump 130 has a hexagonal planar shape that covers the twenty via holes 125, but is not necessarily limited thereto. The bump 130 can have various other shapes, such as a circle, a rectangle, or an octagon.

While the sizes of the bumps 130 are the same, for example, the width of the plurality of via holes 125 decreases as the number of via holes 125 covered by the bump 130 increases. As the width of the plurality of via holes 125 covered by the same-sized bumps 130 decreases, an upper surface of the bump 130, such as the upper surface of the second portion 130a, becomes flatter. However, when the width of the via hole 125 is below a specific size, a void can form inside the via hole 125 in a subsequent process in which the bump 130 is formed. The width of the via hole 125 has a minimum width that enables smooth electrical connection between the bump 130 and the semiconductor substrate 110, and a maximum number of the via holes 125 are formed. For example, as many via holes 125 as possible are formed under each bump 130.

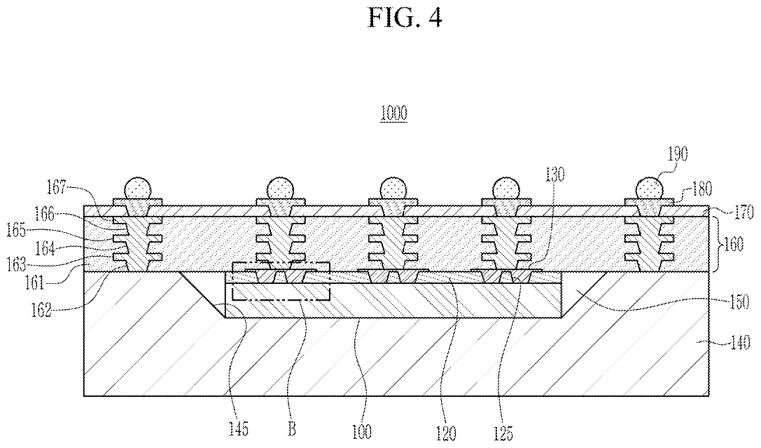

FIG. 4 is a cross-sectional view of a semiconductor package 1000 of an embodiment. The semiconductor package 1000 may include the package substrate 140, the semiconductor chip 100, a redistribution structure 160 and a connection member 190. The semiconductor chip 100 of FIG. 4 is the semiconductor chip 100 described above with reference to FIG. 1, FIG. 2, and FIG. 3A to FIG. 3C.

The package substrate 140 includes a trench 145. The trench 145 has a recessed shape that extends from a first surface of the package substrate 140 toward a second surface that faces the first surface.

In an embodiment, the package substrate 140 is an embedded trace substrate (ETS). For example, the package substrate 140 includes a circuit pattern in a region that surrounds the trench 145. In an embodiment, the package substrate 140 includes conductive posts in the region that surrounds the trench 145. A conductive post includes, for example, a conductive material such as copper, iron, aluminum, or silver.

The semiconductor chip 100 is positioned within the trench 145 of the package substrate 140. A remaining space of the trench 145 is filled with a sealing member 150. The semiconductor chip 100 is sealed to the package substrate 140 by the sealing member 150. The sealing member 150 seals a side surface of the semiconductor chip 100 and an inner wall of the trench 145.

The semiconductor chip 100 includes the semiconductor substrate 110, the insulation layer 120 and the bump 130. The insulation layer 120 is positioned on the semiconductor substrate 110, and includes the plurality of via holes 125. The bump 130 is positioned within the plurality of via holes 125 and on the insulation layer 120. Since the semiconductor chip 100 has been described with reference to FIG. 1, FIG. 2, and FIG. 3A to FIG. 3C, duplicate descriptions will be omitted.

The redistribution structure 160 is positioned on the semiconductor chip 100. The redistribution structure 160 includes a plurality of wiring layers 163, 165, and 167, an interlayer insulation layer 161 positioned between the plurality of wiring layers 163, 165, and 167, first redistribution vias 164 and 166 that penetrate the interlayer insulation layer 161 and interconnects the plurality of wiring layers 163, 165, and 167, and a second redistribution via 162 that penetrates the interlayer insulation layer 161 and interconnects the semiconductor chip 100 and a lowermost wiring layer of the plurality of wiring layers 163, 165, and 167.

The plurality of wiring layers 163, 165, and 167 include a first wiring layer 163, a second wiring layer 165 positioned on the first wiring layer 163, and a third wiring layer 167 positioned on the second wiring layer 165. For example, the first wiring layer 163 is a lowermost wiring layer. The lowermost wiring layer is a wiring layer closest to the semiconductor chip 100. FIG. 4 shows that the redistribution structure 160 includes three layers, but embodiments are not necessarily limited thereto, and in other embodiments, the redistribution structure 160 includes more or fewer number of layers.

The first redistribution vias 164 and 166 connect between the first wiring layer 163 and the second wiring layer 165, and between the second wiring layer 165 and the third wiring layer 167.

The second redistribution via 162 connects the semiconductor chip 100 to the first wiring layer 163, which is lowermost wiring layer of the plurality of wiring layers 163, 165, and 167. The second redistribution via 162 is in contact with the bump 130 of the semiconductor chip 100. A surface where the second redistribution via 162 and the bump 130 are in contact with each other is flat. For example, a size (width) of the second redistribution via 162 is 20 μm or more and 30 μm or less.

The interlayer insulation layer 161 surrounds side surfaces of the plurality of wiring layers 163, 165, and 167, and side surfaces of the first redistribution vias 164 and 166 and the second redistribution via 162. For example, vias or wiring layers are formed by selectively etching the interlayer insulation layer 161 layer by layer and filling the etched portion with a conductive material. The plurality of wiring layers 163, 165, and 167, the first redistribution vias 164 and 166 and the second redistribution via 162 include at least one of copper, aluminum, tungsten, nickel, gold, tin, or titanium, or an alloy thereof.

In an embodiment, the interlayer insulation layer 161 includes a photo imageable dielectric (PID). The photo imageable dielectric (PID) includes, for example, one or more of a polyimide-based photoactive polymer, a novolac-based photoactive polymer, polybenzoxazole, a silicone-based polymer, an acrylate-based polymer, or an epoxy-based polymer.

The semiconductor package 1000 includes a pad insulation layer 170 positioned on the redistribution structure 160, and a plurality of pad portions 180 positioned within a plurality of openings of the pad insulation layer 170. A pad portion 180 is connected to at least one of the plurality of wiring layers 163, 165, and 167.

The pad portion 180 is positioned between the redistribution structure 160 and the connection member 190. For example, the pad portion 180 is positioned above the redistribution structure 160 and under the connection member 190. The pad unit 180 may be referred to as, for example, an under bump metallurgy (UBM) pad. A first surface of the pad portion 180 is in contact with the third wiring layer 167, which is an uppermost layer of the plurality of wiring layers 163, 165, and 167. The first surface of the pad portion 180 in contact with the third wiring layer 167 faces a second surface of the pad portion 180 in contact with the connection member 190. The pad portion 180 includes, for example, at least one of copper, nickel, zinc, gold, silver, platinum, palladium, chromium, or titanium, or an alloy thereof.

The connection member 190 is connected to the redistribution structure 160 through the pad portion 180. The connection member 190 electrically connects the redistribution structure 160 to external configurations through the pad portion 180. In an embodiment, the connection member 190 is a solder ball. The connection member 190 includes, for example, at least one of tin, silver, lead, nickel, or copper, or an alloy thereof.

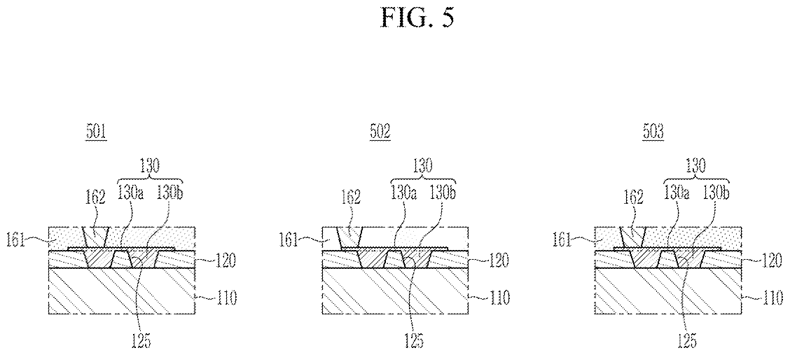

FIG. 5 is an enlarged view of region B of FIG. 4. FIG. 5 shows various examples 501, 502, and 503 of positions where the second redistribution vias 162 are formed on the bumps 130. The second redistribution via 162 connects the semiconductor chip 100 to a lowermost wiring layer, such as the first wiring layer 163, of the plurality of wiring layers 163, 165, and 167 of the redistribution structure 160 in FIG. 4.

Referring to FIG. 5, in some embodiments, the bump 130 includes the plurality of first portions 130b and the second portion 130a. The plurality of first portions 130b are positioned within the plurality of via holes 125 of the insulation layer 120. The second portion 130a interconnects the plurality of first portions 130b.

The plurality of first portions 130b cover sidewalls and the bottom surfaces of the plurality of via holes 125. The plurality of first portions 130b that cover the sidewalls of the plurality of via holes 125 are in contact with the insulation layer 120. The plurality of first portions 130b that cover the bottom surfaces of the plurality of via holes 125 are in contact with the semiconductor substrate 110.

The second portion 130a interconnects the plurality of first portions 130b. The second portion 130a covers the plurality of first portions 130b and those portions of the insulation layer 120 adjacent to the plurality of first portions 130b. The upper surfaces of the plurality of first portions 130b are in contact with the bottom surface of the second portion 130a.

The upper surface of the second portion 130a is flat. For example, flatness of the upper surface of the second portion 130a means that there is substantially no step difference between portions the upper surface of the second portion 130a that overlap a bottom surface of the via hole 125, portions that overlap a sidewall of the via hole 125, and portions that overlap the insulation layer 120 adjacent to the sidewall of the via hole 125, or that the steps thereof are within a predetermined range.

The second redistribution via 162 is formed on the upper surface of the second portion 130a of the bump 130. Referring to a first example 501, the second redistribution via 162 overlaps the bottom surface of the via hole 125 of the insulation layer 120, in a plan view. The second redistribution via 162 is in contact with a portion of the upper surface of the second portion 130a that overlaps the bottom surface of the via hole 125.

Referring to a second example 502, the second redistribution via 162 overlaps the sidewall of the via hole 125 of the insulation layer 120 and the portion of the insulation layer 120 adjacent to the sidewall of the via hole 125, in a plan view. The second redistribution via 162 is in contact with a portion of the upper surface of the second portion 130a that overlaps the sidewall of the via hole 125 and the insulation layer 120 adjacent thereto.

Referring to a third example 503, the second redistribution via 162 overlaps the bottom surface of the via hole 125 of the insulation layer 120, the sidewall of the via hole 125, and the portion of the insulation layer 120 adjacent to the sidewall of the via hole 125, in a plan view. The second redistribution via 162 is in contact with a portion of the upper surface of the second portion 130a that overlaps the bottom surface of the via hole 125, the sidewall of the via hole 125, and the insulation layer 120 adjacent to the sidewall of the via hole 125.

Since the upper surface of the second portion 130a is flat in each of the first example 501, the second example 502, and the third example 503, the surface where the second redistribution via 162 and the bump 130 are in contact with each other is flat, and reliability of the second redistribution via 162 can be secured.

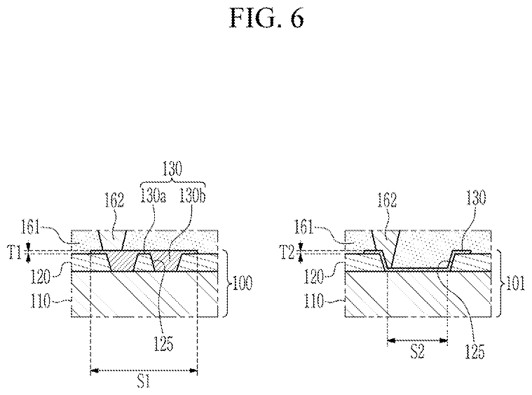

FIG. 6 shows the semiconductor chip 100 of an embodiment and the second redistribution vias 162 formed on the bump 130 of a semiconductor chip 101 of a comparative example.

Referring to FIG. 6, the semiconductor chip 100 of an embodiment includes the semiconductor substrate 110, the insulation layer 120 and the bump 130. The insulation layer 120 is positioned on the semiconductor substrate 110, and includes the plurality of via holes 125. For example, the bump 130 is plated to cover the plurality of via holes 125 and the portion of the insulation layer 120 adjacent to the plurality of via holes 125. The bump 130 includes the plurality of first portions 130b positioned within the plurality of via holes 125 and the second portion 130a that interconnects the plurality of first portions 130b. The bump 130 fills the plurality of via holes 125. The upper surface of the second portion 130a is flat.

The semiconductor chip 101 of the comparative example includes the semiconductor substrate 110, the insulation layer 120 and the bump 130. The insulation layer 120 is positioned on the semiconductor substrate 110, and includes at least one via hole 125. For example, the bump 130 is plated to cover the via hole 125 and the portion of the insulation layer 120 adjacent to the via hole 125. The bump 130 includes a portion that covers the bottom surface of the via hole 125, a portion that covers the sidewall of the via hole 125, and the portion that covers the insulation layer 120 adjacent to the sidewall of the via hole 125. An interior of the via hole 125 is an empty space. A step difference exists between the portion of the bump 130 that covers the bottom surface of the via hole 125, the portion that covers the sidewall of the via hole 125, and the portion that covers the insulation layer 120 adjacent to the sidewall of the via hole 125. The upper surface of the bump 130 is not flat.

The bump 130 of the semiconductor chip 100 of an embodiment and the bump 130 of the semiconductor chip 101 of the comparative example have the same size (width or length). The via holes need to be smaller for a space of the same size to contain a greater number of holes. Since the semiconductor chip 100 of an embodiment includes more via holes 125 than the semiconductor chip 101 of the comparative example, the width of each via hole 125 of the semiconductor chip 100 of an embodiment is less than the width of each via hole 125 of the semiconductor chip 101 of the comparative example.

As the size of the hole is smaller, the ability of filling the holes increases. For example, a plating thickness T1 of the bump 130 of the semiconductor chip 100 of an embodiment and a plating thickness T2 of the bump 130 of the semiconductor chip 101 of the comparative example are equal. Even if the plating thicknesses are equal, the ability of filling the smaller via hole 125 in the semiconductor chip 100 of an embodiment is greater than the ability of filling the via hole 125 in the semiconductor chip 101 of the comparative example. Accordingly, the upper surface of the bump 130 in the semiconductor chip 100 of an embodiment is flatter than the upper surface of the bump 130 in the semiconductor chip 101 of the comparative example.

The second redistribution via 162 that penetrates the interlayer insulation layer 161 and connects the lowermost redistribution layer to the semiconductor chips 100 or 101 is positioned on the semiconductor chip 100 of an embodiment, and on the semiconductor chip 101 of the comparative example. The second redistribution via 162 is in contact with the bump 130.

Since the upper surface of the bump 130 of the semiconductor chip 100 of an embodiment is flat, the surface formed on the bump 130, where the second redistribution via 162 and the bump 130 are in contact with each other, is flat. Since the upper surface of the bump 130 of the semiconductor chip 101 of the comparative example is not flat, the contact surface between the bump 130 and the second redistribution via 162 formed on the bump 130 is stepped.

For example, as shown in FIG. 6, in a plan view, when the second redistribution via 162 is formed to further overlap the sidewall of the via hole 125 and/or the portion of the insulation layer 120 adjacent to the sidewall of the via hole 125 as well as the bottom surface of the via hole 125, the surface where the second redistribution via 162 is in contact with the bump 130 of the semiconductor chip 100 of an embodiment is flat, and the surface where the second redistribution via 162 is in contact with the bump 130 of the semiconductor chip 101 of the comparative example is stepped.

As the surface where the second redistribution via 162 contacts the bump 130 is flatter in an embodiment, reliability of the second redistribution via 162 is increased. The second redistribution via 162 formed on the semiconductor chip 100 of an embodiment has greater reliability than the second redistribution via 162 formed on the semiconductor chip 101 of the comparative example.

In the semiconductor chip 101 of the comparative example, the surface area of the upper surface of the bump 130 where the bump 130 in contact with the second redistribution via 162 is flat may be expressed as S2 in a cross-section. In a plan view, S2 corresponds to an area where the bump 130 overlaps the bottom surface of the via hole 125. In the semiconductor chip 100 of an embodiment, the surface area of the upper surface of the bump 130 where the bump 130 in contact with the second redistribution via 162 is flat may be expressed as S1 in a cross section. In a plan view, S1 corresponds to an area where the bump 130 overlaps the bottom surface of the via hole 125, the sidewall of the via hole 125, and the portion of the insulation layer 120 adjacent to the sidewall of the via hole 125. For example, S1 is the entire area of the bump 130. S1 is greater than S2.

The area of surface of the bump 130 in contact with the second redistribution via 162 and that is flat may be referred to as a substantially usable area of the bump 130. The substantially usable area S1 of the bump 130 of the semiconductor chip 100 of an embodiment is greater than the substantially usable area S2 of the bump 130 of the semiconductor chip 101 of the comparative example.

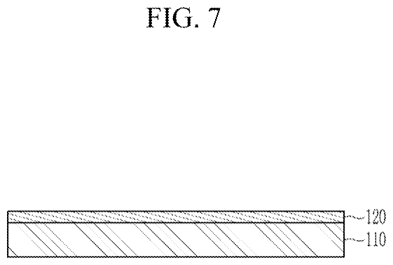

FIG. 7 to FIG. 13 illustrate a method of manufacturing the semiconductor chip 100 of an embodiment. The manufacturing method shown in FIG. 7 to FIG. 13 is a part of a method of manufacturing the semiconductor chip 100 described above with reference to FIG. 1, FIG. 2, and FIG. 3A to FIG. 3C. For example, a manufacturing method shown in FIG. 7 to FIG. 13 is an exemplary, non-limiting method for forming the bump 130 of the semiconductor chip 100.

Referring to FIG. 7, in an embodiment, the insulation layer 120 is formed on the semiconductor substrate 110. The insulation layer 120 includes, for example, at least one of silicon nitride, silicon oxide, silicon oxynitride, or a photosensitive polyimide (PSPI), or a combination thereof. The insulation layer 120 can be formed on the semiconductor substrate 110 by a deposition or coating process.

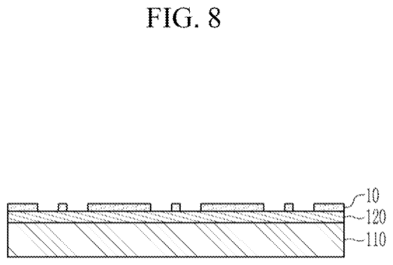

Referring to FIG. 8, in an embodiment, a first photoresist pattern 10 is formed on the insulation layer 120. For example, the first photoresist pattern 10 is formed by coating a first photoresist layer on the insulation layer 120 and exposing and developing a photomask that overlays the first photoresist layer.

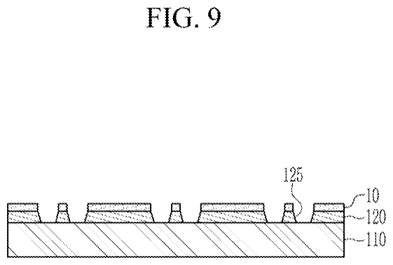

Referring to FIG. 9, in an embodiment, the insulating layer 120 is etched by using the first photoresist pattern 10 as a mask. The plurality of via holes 125 are formed in the insulating layer 120 by the etching process.

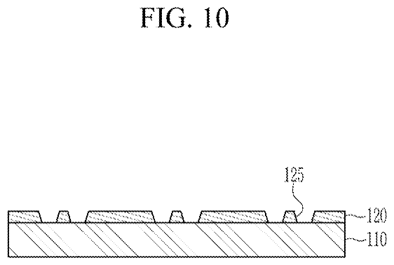

Referring to FIG. 10, in an embodiment, the first photoresist pattern 10 is removed. For example, the first photoresist pattern 10 is removed by wet etching. The insulation layer 120 includes the plurality of via holes 125.

For example, when the insulation layer 120 is made of a photosensitive polyimide, a patterning process of forming the plurality of via holes 125 by exposure is performed without forming a separate photoresist layer. For example, since the photoresist layer is not formed when the insulating layer 120 is made of a photosensitive polyimide, the process of removing the photoresist pattern, such as the first photoresist pattern 10, is also omitted.

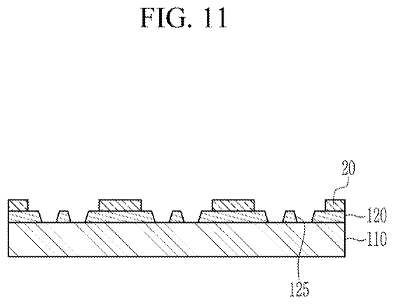

Referring to FIG. 11, in an embodiment, a second photoresist pattern 20 is formed on the insulation layer 120. For example, the second photoresist pattern 20 is formed by coating a second photoresist layer on the insulation layer 120 and the portions of the semiconductor substrate 110 exposed through the plurality of via holes 125, and exposing and developing a photomask that overlays the second photoresist layer. The plurality of via holes 125 and portions of the insulation layers 120 adjacent to the sidewalls of the plurality of via holes 125 are exposed by the second photoresist pattern 20.

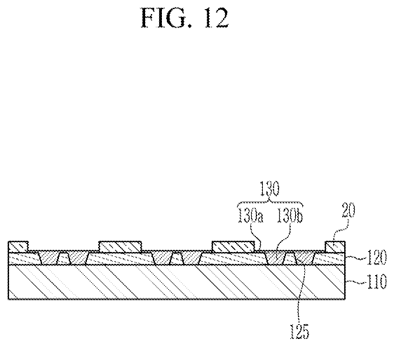

Referring to FIG. 12, in an embodiment, a plating process is performed on a region exposed by the second photoresist pattern 20. A conductive material is plated on the region exposed by the second photoresist pattern 20 through the plating process. The material plated on the region exposed by the second photoresist pattern 20 includes, for example, copper. For example, copper is plated by electroplating. The bump 130 is formed by the plating process within the plurality of via holes 125 and on portions of the insulation layer 120 that are exposed by the second photoresist pattern 20. The bump 130 includes the plurality of first portions 130b positioned within the plurality of via holes 125 and the second portion 130a that interconnects the plurality of first portions 130b.

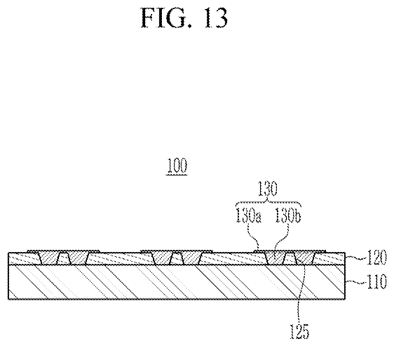

Referring to FIG. 13, in an embodiment, the second photoresist pattern 20 is removed. For example, the second photoresist pattern 20 is removed by wet etching. The semiconductor chip 100 includes the bump 130 that covers the plurality of via holes 125 and the portion of the insulation layer 120 adjacent to the plurality of via holes 125. The plurality of first portions 130b of the bump 130 cover sidewalls and the bottom surfaces of the plurality of via holes 125. The second portion 130a of the bump 130 covers the plurality of via holes 125 and the portion of the insulation layer 120 adjacent to sidewalls of the plurality of via holes 125. The upper surface of the second portion 130a is flat.

While embodiments of the present disclosure have been described in connection with the accompanying drawings, it is to be understood that embodiments of the disclosure are not limited to the disclosed embodiments, but, on the contrary, are intended to cover various modifications and equivalent arrangements included within the spirit and scope of the appended claims.

What is claimed is:

1. A semiconductor chip, comprising:
a semiconductor substrate;
an insulation layer positioned on the semiconductor substrate and that comprises a plurality of via holes; and
a bump positioned within the plurality of via holes and on the insulation layer,
wherein portions of the bump positioned within the plurality of via holes are connected to each other.

2. The semiconductor chip of claim 1, wherein, in a plan view, the bump covers a first surface of the insulation layer that surrounds surfaces of the plurality of via holes.

3. The semiconductor chip of claim 1, wherein a width of each of the plurality of via holes is 5 μm or more and 10 μm or less.

4. The semiconductor chip of claim 1, wherein the bump contains copper, and a thickness of the bump is 3 μm or more and 5 μm or less.

5. The semiconductor chip of claim 1, wherein:
the number of via holes covered by the bump is four; and
the bump has a hexagonal planar shape that covers the four via holes.

6. The semiconductor chip of claim 1, wherein:
planar shapes of each of the plurality of via holes are circular.

7. The semiconductor chip of claim 1, wherein the insulation layer contains a photosensitive polyimide.

8. A semiconductor chip, comprising:
a semiconductor substrate;
an insulation layer positioned on the semiconductor substrate and that comprises a plurality of via holes; and
a bump positioned within the plurality of via holes and on portions of the insulation layer,
wherein the bump comprises:
a plurality of first portions positioned within the plurality of via holes; and
a second portion that interconnects the plurality of first portions.

9. The semiconductor chip of claim 8, wherein an upper surface of the second portion is flat.

10. The semiconductor chip of claim 8, wherein the second portion covers the plurality of first portions and a portion of the insulation layer adjacent to the plurality of first portions.

11. The semiconductor chip of claim 8, wherein the plurality of first portions cover sidewalls and bottom surfaces of the plurality of via holes.

12. The semiconductor chip of claim 8, wherein upper surfaces of the plurality of first portions are in contact with a bottom surface of the second portion.

13. The semiconductor chip of claim 8, wherein the plurality of first portions have a pillar shape in contact with inner walls of the plurality of via holes.

14. A semiconductor package, comprising:
a package substrate that comprises a trench;
a semiconductor chip positioned within the trench of the package substrate;
a redistribution structure positioned on the semiconductor chip; and
a connection member connected to the redistribution structure,
wherein the semiconductor chip comprises:
a semiconductor substrate;
an insulation layer positioned on the semiconductor substrate and that comprises a plurality of via holes; and
a bump positioned within the plurality of via holes and on portions of the insulation layer,
wherein the bump comprises:
a plurality of first portions positioned within the plurality of via holes; and
a second portion that interconnects the plurality of first portions.

15. The semiconductor package of claim 14, wherein the redistribution structure comprises:
a plurality of wiring layers;
an interlayer insulation layer positioned between the plurality of wiring layers;
a first redistribution via that penetrates the interlayer insulation layer and interconnects the plurality of wiring layers; and
a second redistribution via that penetrates the interlayer insulation layer and interconnects the semiconductor chip and a lowermost wiring layer of the plurality of wiring layers.

16. The semiconductor package of claim 15, wherein the second redistribution via is in contact with the bump.

17. The semiconductor package of claim 16, wherein a surface where the second redistribution via and the bump are in contact with each other is flat.

18. The semiconductor package of claim 16, wherein:
the second redistribution via overlaps a bottom surface of the via hole of the insulation layer, in a plan view.

19. The semiconductor package of claim 16, wherein:
the second redistribution via overlaps a sidewall of the via hole of the insulation layer and a portion of the insulation layer adjacent to the sidewall, in a plan view.

20. The semiconductor package of claim 16, wherein the second redistribution via overlaps a bottom surface of the via hole of the insulation layer, a sidewall of the via hole, and a portion of the insulation layer adjacent to the sidewall, in a plan view.
